(19) United States
(12) Patent Application Publication
(10) Pub. No.: US 2024/0363584 A1
(43) Pub. Date: Oct. 31, 2024

(54) METHOD OF MANUFACTURING SEMICONDUCTOR DEVICES

(71) Applicant: STMicroelectronics International N.V., Geneva (CH)

(72) Inventors: Antonio BELLIZZI, Cologno Monzese (IT); Nicoletta MODARELLI, Milano (IT)

(73) Assignee: STMicroelectronics International N.V., Geneva (CH)

(21) Appl. No.: 18/637,865

(22) Filed: Apr. 17, 2024

(30) Foreign Application Priority Data
Apr. 27, 2023 (IT) 102023000008289

(51) Int. Cl. H01L 23/00; H01L 21/56

(52) U.S. Cl. CPC H01L 24/97; H01L 21/561; H01L 24/48; H01L 2224/48175; H01L 2224/97

(57) ABSTRACT

Semiconductor dice are arranged onto a first surface of a common electrically conductive substrate. The common electrically conductive substrate has a second surface opposite the first surface and includes substrate portions and elongated sacrificial connecting bars extending between adjacent substrate portions. Insulating material is coated on the second surface of the elongate sacrificial connecting bars. Solder material is grown on the second surface of the common electrically conductive substrate. The insulating material counters growth of the solder material on the second surface of the elongate sacrificial connecting bars. Singulated individual semiconductor devices are provided by cutting the common electrically conductive substrate along the length of the elongate sacrificial connecting bars having the insulating material coated on its second surface.

### PRIORITY CLAIM

This application claims the priority benefit of Italian Application for Patent No. 102023000008289, filed on Apr. 27, 2023, the content of which is hereby incorporated by reference in its entirety to the maximum extent allowable by law.

### TECHNICAL FIELD

The description relates to manufacturing semiconductor devices.

Solutions as described herein can be applied to integrated circuit (IC) semiconductor devices provided with a Quad Flat No-leads (QFN) package for automotive products, for instance.

### BACKGROUND

Wettable flanks are a desirable feature of integrated circuits semiconductor devices in as much as they enhance solderability of the devices to the final substrate, such as a printed circuit board (PCB), for instance.

Moreover, wettable flanks facilitate automatic optical inspection (AOI) of the solder joint thanks to the formation of a solder meniscus at the flank of the device when soldered to the final substrate.

When concurrently processing a plurality of (IC) semiconductor devices, wettable flanks are conventionally provided via a “half-cut” at the connecting bars which run along the periphery of each individual device. In fact, in current manufacturing processes of (IC) semiconductor devices, a plurality of substrates (leadframes) for individual devices are held together in a leadframe strip using metallic connecting structures including (sacrificial) connecting bars running along the periphery of each device. Multiple devices are thus concurrently processed and finally singulated into individual devices.

Prior to the singulation step, a plating step can be performed in order to plate the leadframe bottom surface with a metallic (solderable) layer, made of tin for instance. The “half-cut” may cause the connecting bars to be exposed at the surface of the leadframe strip during the plating step causing the connecting bars to be plated with a relatively large amount of tin.

A singulating blade removes the connecting bars and the solderable metallic layer plated thereon. Due to the amount of metal accumulated on the connecting bars, the action of the blade during the singulation step may produce flakes or filaments that undesirably “bridge” neighboring leads causing a short circuit therebetween.

Such undesired electrical couplings (“shorts”) may cause failure and consequent rejection of the device.

There is a need in the art for a solution aimed at addressing the issues discussed in the foregoing.

### SUMMARY

One embodiment herein comprises a method.

In solutions as described herein, a processing step is added to the assembly flow in order to counter the formation of filaments/flakes which could cause failure of the device.

In solutions as described herein, the connecting bars that are exposed during the plating step are covered with an insulating material to counter growth/deposition of solderable material on the connecting bars.

Solutions as described herein may be advantageously applied to Quad Flat No-leads (QFN) packages provided with wettable flanks.

### BRIEF DESCRIPTION OF THE DRAWINGS

One or more embodiments will now be described, by way of example only, with reference to the annexed figures, wherein:

FIGS. 1A, 1B; 2A, 2B; and 3A, 3B are pairs of cross-sectional and plan views, respectively, illustrative of conventional processing steps to provide semiconductor devices with wettable flanks;

FIG. 4 is a plan view illustrative of a processing step according to embodiments of the present description;

FIGS. 5A and 5B are a plan view and a perspective view, respectively, illustrative of a further processing step according to embodiments of the present description; and

FIG. 6 is a plan view illustrative of a final singulation step of devices processed according to embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

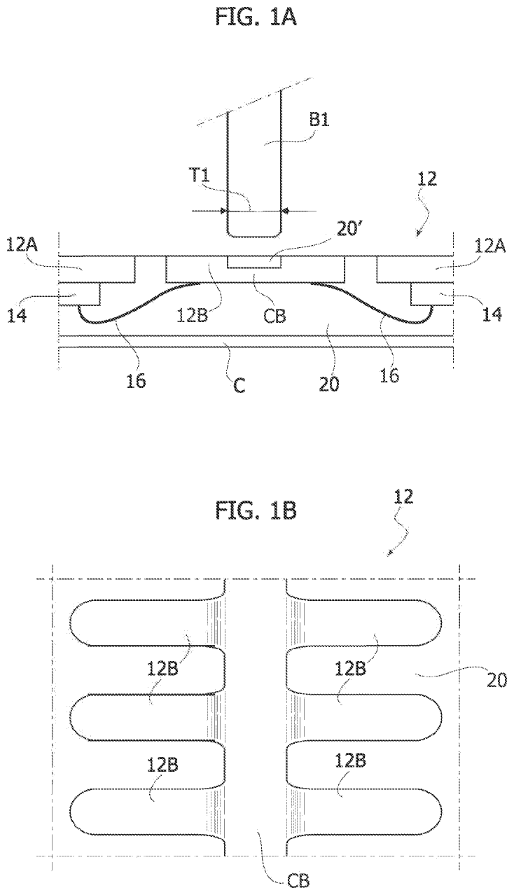

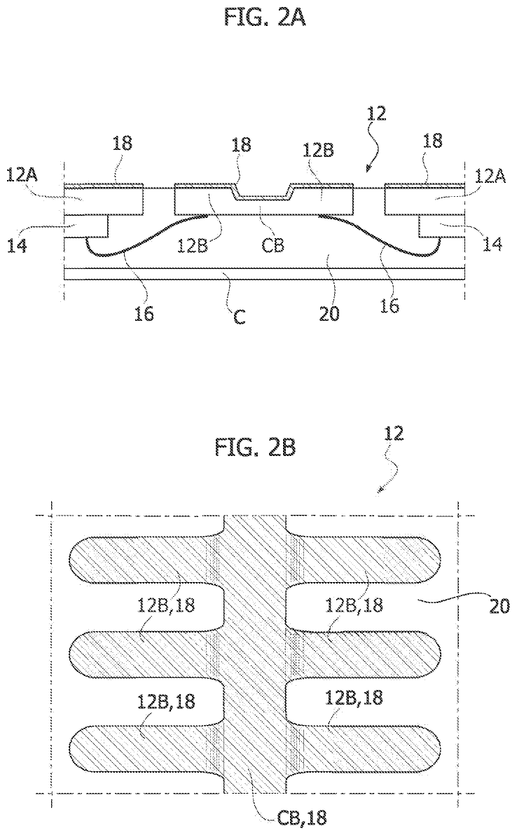

FIGS. 1A, 1B; 2A, 2B; and 3A, 3B are pairs of cross-sectional and plan views, respectively, illustrative of processing steps according to a conventional approach intended to provide integrated circuit semiconductor (silicon, for instance) devices with wettable flanks.

FIG. 1A illustrates a portion of a leadframe reel comprising a plurality of semiconductor devices under (concurrent) processing.

As conventional in the art, these devices comprise a substrate (leadframe) having arranged thereon one or more semiconductor chips or dice 14. As used herein, the terms chip/s and die/dice are regarded as synonymous.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip (the terms chip/s and die/dice are regarded as synonymous) to other electrical components or contacts.

Essentially, a leadframe comprises an array of electrically-conductive formations (or leads, 12B for instance) that from an outline location extend inwardly in the direction of a semiconductor chip or die thus forming an array of electrically-conductive formations from a die pad (12A in FIG. 1, for instance) configured to have at least one (integrated circuit) semiconductor chip or die attached on the top/front surface thereof. This may be via conventional means such as a die attach adhesive (a die attach film (DAF), for instance).

In certain cases, a leadframe can be of the pre-molded type, that is a type of leadframe comprising a sculptured metal (e.g., copper) structure formed by etching a metal sheet and comprising empty spaces that are filled by an insulating compound (a resin, for instance) “pre-molded” on the sculptured metal structure.

In current manufacturing processes of (integrated circuit) semiconductor devices plural devices/leadframes are processed concurrently. Concurrent processing of a plurality of devices is achieved by providing a common substrate 12 (e.g., a leadframe strip) comprising a plurality of individual substrates for each device.

In order to concurrently process several devices, several (individual) leadframes are arranged in a leadframe strip 12 and held together via sacrificial connecting bars CB running at the periphery of the individual leadframes.

In the case exemplified in FIG. 1A, and in the corresponding plan view of FIG. 1B, two devices in the leadframe strip 12 are connected to the same connecting bar CB via their leads 12B. More generally, individual leadframes may be connected to the connecting bars CB both via leads 12B and/or die pads 12A. In certain cases, so-called tie bars may be provided, that is, bridge-like formations that connect the die pads (12A, for instance) or the leads (12B, for instance) of a leadframe to the connecting bars.

As illustrated in the figures, devices in the leadframe strip 12 may comprise: electrically conductive wires 16 providing electrical coupling between the dice 14 and the leads 12B; and a molding compound 20 providing an insulating encapsulation to the (IC) semiconductor devices.

Processing of semiconductor devices to obtain devices as illustrated in FIG. 1A is conventional in the art thus making unnecessary a more detailed description herein.

The leadframe strip 12 having the chips 14 arranged thereon and provided with the insulating encapsulation of molding compound 20 may be arranged on a carrier C, as illustrated in FIGS. 1A to 3A, with its bottom/back surface up in order to facilitate further processing.

It is noted that the sequence of steps of FIGS. 1A, 1B; 2A, 2B, and 3A, 3B is merely exemplary insofar as one or more steps illustrated in the figures can be omitted, performed in a different manner (with other tools, for instance) and additional steps may be added.

FIG. 1A illustrates a processing step in providing devices comprised in the leadframe reel with wettable flanks.

As illustrated, connecting bars CB may be “half-etched” and are not exposed at the bottom/back surface of the leadframe reel due to the (pre-) molding compound 20′ covering them.

The term “half-etching” is a common designation in the art, which does not imply that such partial etching is by necessity to exactly half the thickness of the base sculptured structure of the leadframe.

A first blade (or saw) B1, having a first thickness T1 (or blade width), is used to perform a partial cut at the connecting bars CB which removes the molding compound 20′ covering the connecting bars CB. As illustrated in FIG. 1B connecting bars CB are now exposed on the bottom surface of the leadframe reel.

FIGS. 2A and 2B illustrate a plating step where a layer of solderable material 18 (for instance, tin) is grown/deposited on the second (bottom) surface of the leadframe reel. As illustrated the exposed surfaces of conductive material (that is, the metallic material of the leadframe) are plated with a layer of solderable material 18. Due to the removal of the molding compound 20′ the connecting bars CB are left uncovered during the plating step and are thus plated with a layer of solderable material 18 (tin, for instance).

FIG. 3A illustrates a final singulation step where the leadframe reel is cut into individual devices. A second, thinner blade B2 having a thickness (or blade width) T2<T1 may be used to perform a full cut of the leadframe reel resulting in the formation of wettable flanks WF on at the periphery of each individual device.

A solderable layer 18 together with wettable flanks WF provided at the periphery of the package enhance solderability of the device to the support substrate the device is intended to be mounted (soldered) on, such as a printed circuit board (PCB) for instance.

Moreover, wettable flanks WF cause the formation of a solder meniscus which facilitates automatic optical inspection of the devices soldered/mounted on the substrate.

However, the conventional approach just described may give raise to some issues due to the fact that connecting bars CB are covered with solderable material when the singulation step is performed.

As illustrated in FIG. 3B, due to the relatively large amount of solderable material 18 (tin, for instance) plated on the connecting bars CB, filaments or flakes F may form as a consequence of the cutting action of the singulating blade B2.

As illustrated, filaments/flakes F may establish electrical contact between two neighboring leads 12B, causing an undesired short circuit therebetween and consequent failure (and rejection) of the device.

Formation of filaments F and related issues may be mitigated by frequently replacing the singulation blade B2. In fact, it is observed that filaments F are increasingly formed as the blade deteriorates.

However, frequently replacing the singulating blade may involve higher manufacturing costs and time since the production is halted in order to replace a singulating blade.

In solutions as described herein, formation of filaments/flakes F is reduced by countering plating of the connecting bars CB thus reducing the amount of solderable material the blade removes during singulation.

In solutions as described herein, an insulating material is formed (coated) on the exposed (bottom) surface of the connecting bars CB to counter plating thereof.

Solutions as described herein provide a time-effective and cost-effective way to reduce the likelihood of possible formation of filaments F likely to short neighboring leads 12B, thus reducing the number of rejected devices.

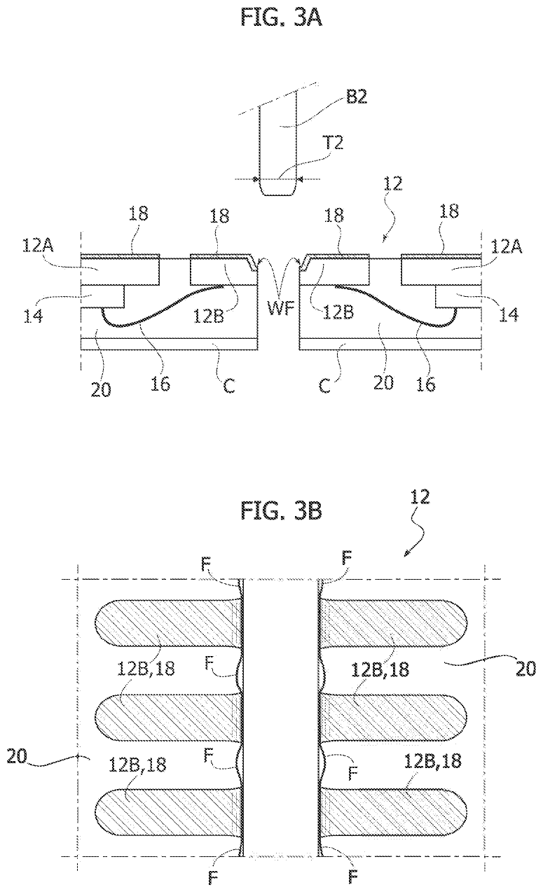

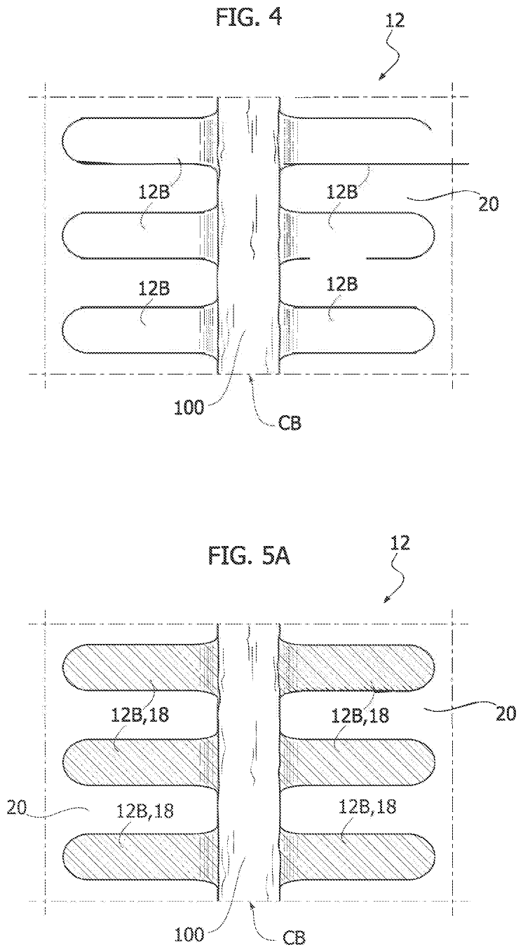

FIG. 4 illustrates a portion of the second (back or bottom) surface of a leadframe reel after a partial cut has been performed to remove the molding compound 20 (the portion of molding compound indicated with the reference 20′ in FIG. 1A) and exposing the connecting bars CB.

As illustrated, a mass of insulating material 100 is formed on the second surface of the connecting bars CB that is exposed as a consequence of the removal of a portion of molding/encapsulation compound 20′ (via a partial cut as illustrated in FIG. 1A, for instance). This partial cut forms a channel across each connecting bar CB having a bottom surface and sidewall surfaces. It will be noted that the mass of insulating material 100 forms a layer covering the bottom surface of the channel produced by the partial cut. This layer has a thickness which is much less than the thickness of the maolding compound material 20′ removed by the partial cut. Because of this difference in thickness, the sidewall surfaces of the partial cut portion of the connecting bars CB remain exposed and are receptive to the deposition or growth of the solderable layer 18.

The insulating material 100 may be formed on the connecting bars CB by any method known to those skilled in the art; possible techniques to form/coat insulating material 100 comprise, for instance: dispensing with a needle, where the amount of material 100 dispensed is controlled via the needle diameter; jetting, that is, a non-contact method where droplets of insulating material are ejected via a piezoelectric valve; or laser induced forward transfer (LIFT) which comprises a deposition process where material from a donor tape or sheet is transferred to an acceptor substrate facilitated by laser pulses. General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

No matter which process technique is used to form this coating, the insulating material 100 counters deposition of the solderable layer 18 on the connecting bars CB, thus reducing the amount of solderable material that is removed by the blade (the blade B2 illustrated in FIG. 3A, for instance) in the singulations step.

Reducing the amount of solderable material grown/deposited on the connecting bars CB reduces the risk of filaments formation due to the cutting action of the blade during the final singulation step.

The insulating material 100 may be chosen to be a curable material in order to make it resistant to the chemicals used by the plating bath.

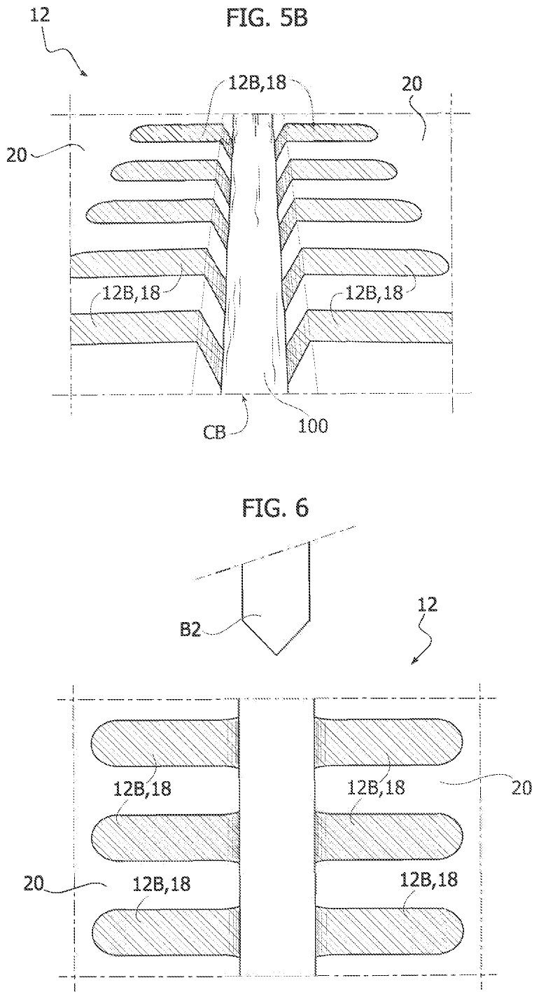

FIGS. 5A and 5B are, respectively, a plan view and a perspective view of a portion of the second (bottom) surface of a leadframe reel after a plating step is performed.

As illustrated, leads 12B are plated with a layer of solderable material 18 (tin, for instance) as desired, while portions of the connecting bars CB covered with a mass of insulating material 100 are not plated.

As visible in FIG. 5B, insulating material 100 is formed at the bottom of the trench formed during the partial cut (performed via a blade B1 like the one illustrated in FIG. 1A, for instance), leaving the sides of the trench exposed by the insulating material 100. In this way the side surface of the leads 12B are plated with solderable material 18 thus providing wettable flanks WF to the devices in the leadframe strip 12.

FIG. 6 is illustrative of the final singulation step performed via a blade B2, for instance, where the connecting bars CB with the insulating material formed 100 thereon are removed in order to separate the leadframe strip 12 into individual devices.

Cutting during the final singulation step thus take place along the length of the elongate sacrificial connecting bars CB that, at those locations where cutting occurs, are exempt from solder material 18 deposited at the second surface due to the presence of the insulating material 100 coated thereon.

The solderable metallic layer 18 is absent from the surface of the connecting bars CB exposed to cutting and the blade will not contact (notionally) the solderable metallic layer 18 plated on the conductive surfaces of the leadframe strip 12, thus reducing the risk of filament formation.

Moreover, due to the lesser amount of solderable material 18 that is removed during the singulation step, wearing of the singulating blade (B2) is reduced.

As described, the material 100 may be advantageously chosen to be: electrically insulating, in order to counter plating of the connecting bars CB, and curable, in order to be resistant to the plating bath and the chemicals therein.

An example of such a material is the commercially available product LOCTITE® ABLESTIK 2025D, a non-conductive, heat curing, die attach adhesive that has been shown to have the desired qualities discussed in the foregoing.

In summary, solutions as described herein may be advantageously applied in manufacturing processes where a plurality of integrated circuit semiconductor devices are concurrently processed.

A plurality of semiconductor dice 14 is arranged onto a first (front) surface of a common electrically conductive substrate (such as the leadframe strip 12, for instance) that has a second surface opposite the first surface and comprises substrate portions (the individual leadframes comprising die pads 12A and leads 12B).

The common electrically conductive substrate comprises also elongated connecting bars CB extending between adjacent substrate portions.

Insulating material 100 is formed on the second surface of the elongate sacrificial connecting bars CB and, subsequently, solder material 18 (tin, for instance) is grown on the second (that is, back) surface of the common electrically conductive substrate 12 having the insulating material formed on the second surface of the elongate sacrificial connecting bars (CB).

The insulating (and curable) material 100 counters growth of solder material 18 on the second (back) surface of the elongate sacrificial connecting bars CB thus reducing the risk of filaments formation.

The common electrically conductive substrate 12 is finally cut (via sawing with a blade B2, for instance) along the length of the elongate sacrificial connecting bars (CB) having the insulating material (100) formed on the second surface thereof to provide finished individual devices that are notionally exempt of filaments that may cause undesired shorts (and thus rejection of the device).

According to embodiments of the present description, the second (back) surface of the elongate sacrificial connecting bars CB may be exposed as a consequence of a partial cut (via a blade B1 thicker than the singulating blade B2) intended to provide the package of the devices with wettable flanks.

The claims are an integral part of the technical teaching provided in respect of the embodiments.

Without prejudice to the underlying principles, the details and embodiments may vary, even significantly, with respect to what has been described by way of example only without departing from the extent of protection. The extent of protection is determined by the annexed claims.

1. A method, comprising:
arranging a plurality of semiconductor dice onto a first surface of a common electrically conductive substrate, wherein the common electrically conductive substrate has a second surface opposite the first surface and comprises a plurality of substrate portions and elongated sacrificial connecting bars extending between adjacent substrate portions;
encapsulating the plurality of semiconductor dice and the common electrically conductive substrate in a molding compound;
coating an insulating material on the second surface of the common electrically conductive substrate at the elongate sacrificial connecting bars;
growing a solder material on portions of the second surface of the common electrically conductive substrate which are not coated by the insulating material, wherein the insulating material counters growth of the solder material on the second surface of the common electrically conductive substrate at the elongate sacrificial connecting bars; and
providing singulated individual semiconductor devices by cutting through the molding compound and the elongate sacrificial connecting bars of common electrically conductive substrate at portions of the second surface of the common electrically conductive substrate which are coated by the insulating material.

2. The method of claim 1, wherein the insulating material is a heat curable insulating material.

3. The method of claim 1, wherein the solder material comprises tin.

4. The method of claim 1, wherein growing the solder material comprises growing a solderable metallic layer on the second surface of the common electrically conductive substrate via plating.

5. The method of claim 1, wherein coating the insulating material comprises coating the insulating material on the second surface via dispensing or jetting.

6. The method of claim 1, wherein coating the insulating material comprises coating the insulating material on the second surface via laser induced forward transfer (LIFT).

7. The method of claim 1, further comprising:
prior to coating, partially cutting the common electrically conductive substrate starting from the second surface thereof at each elongate sacrificial connecting bar to form a channel having a bottom surface and sidewall surfaces; and
wherein coating the insulating material comprises coating the insulating material on the bottom surface at the channel in each elongate sacrificial connecting bar exposed in response to said partially cutting, but not coating the sidewall surfaces.

8. The method of claim 7, whering partially cutting comprises using a first blade having a first thickness, and wherein providing singulated individual semiconductor devices comprises cutting with a second blade having a second thickness, wherein said first thickness is less than said second thickness.

9. A method, comprising:
arranging a plurality of semiconductor dice onto a first surface of a common electrically conductive substrate, wherein the common electrically conductive substrate has a second surface opposite the first surface and comprises a plurality of substrate portions and elongated connecting bars extending between adjacent substrate portions;
encapsulating the plurality of semiconductor dice and the common electrically conductive substrate in a molding compound;
forming a channel extending across each elongated connecting bar, said channel including a bottom surface and sidewall surfaces;
coating an insulating material layer on the bottom surface of the channel at each elongated connecting bar while leaving the sidewall surfaces of the channel at each elongated connecting bar exposed;
providing a solder material on the exposed sidewall surfaces of the channel at each elongated connecting bar; and
providing singulated individual semiconductor devices by cutting through the molding compound and the elongated connecting bars at the bottom surface of the channel at each elongated connecting bar coated by the insulating material layer.

10. The method of claim 9, further comprising removing an insulating material filling present within the channel before coating.

11. The method of claim 10, wherein said insulating material filling present within the channel has a thickness which is greater than a thickness of the insulating material layer.

12. The method of claim 9, wherein the insulating material layer is a heat curable insulating material.

13. The method of claim 9, wherein the solder material comprises tin.

14. The method of claim 9, wherein coating the insulating material layer comprises providing the insulating material layer on the bottom surface via dispensing or jetting.

15. The method of claim 9, wherein coating the insulating material layer comprises providing the insulating material layer on the bottom surface via laser induced forward transfer (LIFT).

16. The method of claim 9, wherein said channel has a first width and wherein providing singulated individual semiconductor devices by cutting comprises cutting with a blade having a second width less than the first width.

17. A method, comprising:
encapsulating a leadframe in a molding compound;
forming a channel extending across an elongated connecting bar interconnecting adjacent substrate portions of the leadframe, said channel including a bottom surface and sidewall surfaces;
providing an insulating material layer covering the bottom surface of the channel at the elongated connecting bar while leaving the sidewall surfaces of the channel at the elongated connecting bar exposed;
coating a solder material on the exposed sidewall surfaces of the channel at the elongated connecting bar; and
cutting through the molding compound and the elongated connecting bar at the bottom surface of the channel covered by the insulating material layer to produce cut connecting bar portions each having an end surface with wettable flanks.

18. The method of claim 17, wherein the insulating material layer is a heat curable insulating material.

19. The method of claim 17, wherein the insulating material layer is provided on the bottom surface via dispensing or jetting.

20. The method of claim 17, wherein the insulating material layer is provided on the bottom surface via laser induced forward transfer (LIFT).
